(19) United States
(12) Patent Application Publication
(10) Pub. No.: US 2024/0235489 A1
(43) Pub. Date: Jul. 11, 2024

(54) POWER AMPLIFIER CIRCUIT

(71) Applicant: Murata Manufacturing Co., Ltd., Kyoto (JP)

(72) Inventor: Yuri HONDA, Kyoto (JP)

(21) Appl. No.: 18/405,125

(22) Filed: Jan. 5, 2024

(30) Foreign Application Priority Data
Jan. 10, 2023 (JP) 2023-001799

(51) Int. Cl. H03F 1/02; H03F 1/56; H03F 3/21

(52) U.S. Cl. CPC H03F 1/0288; H03F 1/565; H03F 3/211; H03F 2200/387

(57) ABSTRACT

A power amplifier circuit includes a first amplifier, a second amplifier, and, an output terminal. The power amplifier circuit includes an impedance conversion unit connected to an output end of one amplifier, which is either the first amplifier or the second amplifier. The impedance conversion unit includes a first line with one end connected to the output end, a second line with one end connected to another end of the first line, and a first capacitor with one end connected to a connection point between the first line and the second line and with another end connected to a reference potential. The first line and the second line are coupled to each other. A signal based on a connection point between an output end of another amplifier of the first amplifier and the second amplifier and another end of the second line is outputted from the output terminal.

### CROSS REFERENCE TO RELATED APPLICATION

This application claims priority from Japanese Patent Application No. 2023-001799 filed on Jan. 10, 2023. The content of this application is incorporated herein by reference in its entirety.

### BACKGROUND OF THE DISCLOSURE

### 1. Field of the Disclosure

The present disclosure relates to a power amplifier circuit.

### 2. Description of the Related Art

As a type of a power amplifier circuit, there is a Doherty amplifier (for example, U.S. patent Application Publication No. 2021/0184633). The Doherty amplifier includes a peak amplifier and a carrier amplifier that are disposed in parallel. In the Doherty amplifier, only the carrier amplifier operates at a low output power level, and the carrier amplifier and the peak amplifier operate at a high output power level.

### BRIEF SUMMARY OF THE DISCLOSURE

In the power amplifier circuit disclosed in U.S. Patent Application Publication No. 2021/0184633, however, a circuit that processes a harmonic has to be provided for each of the peak amplifier and the carrier amplifier. This interferes with a reduction in circuit size.

The present disclosure has been made in view of the above and aims to provide a power amplifier circuit in which a reduction in circuit size can be achieved.

To solve the above-described issue and achieve the aim, a power amplifier circuit according to an aspect of the present disclosure includes a first amplifier, a second amplifier, and an output terminal. The power amplifier circuit includes an impedance conversion unit connected to an output end of one amplifier, which is either the first amplifier or the second amplifier. The impedance conversion unit includes a first line with one end connected to the output end, a second line with one end connected to another end of the first line, and a first capacitor with one end connected to a connection point between the first line and the second line and with another end connected to a reference potential. The first line and the second line are coupled to each other. A signal based on a connection point between an output end of another amplifier of the first amplifier and the second amplifier and another end of the second line is outputted from the output terminal.

In the power amplifier circuit according to the present disclosure, a reduction in circuit size can be achieved.

### BRIEF DESCRIPTION OF THE SEVERAL VIEWS OF THE DRAWINGS

FIG. 1 is a diagram illustrating an example of a λ/4 transformer used in a Doherty amplifier circuit;

FIG. 2 is a diagram illustrating an example of a more specific configuration of the λ/4 transformer;

FIG. 3 is a diagram illustrating an example of a Doherty amplifier circuit using the λ/4 transformer illustrated in FIG. 2;

FIG. 4 is a diagram illustrating an example of a configuration of a Doherty amplifier circuit;

FIG. 5 is a diagram illustrating a power amplifier circuit according to a first embodiment;

FIG. 6 is a graph illustrating an example of passage loss for frequency;

FIG. 7 is a Smith chart for explaining a characteristic impedance of the power amplifier circuit according to the present disclosure by comparison with that in a comparative example;

FIG. 8 is a Smith chart for explaining a characteristic impedance of the power amplifier circuit according to the present disclosure by comparison with that in the comparative example;

FIG. 9 is a diagram illustrating a power amplifier circuit according to a second embodiment;

FIG. 10 is a plan view illustrating a pattern example in a case where the power amplifier circuit according to the second embodiment is formed on a semiconductor substrate;

FIG. 11 is a perspective view of an impedance conversion unit side as viewed from a harmonic processing circuit side in FIG. 10;

FIG. 12 is a diagram illustrating a power amplifier circuit according to a third embodiment;

FIG. 13 is a diagram for explaining, in a harmonic processing circuit of the power amplifier circuit according to the third embodiment, how the circuit at an even harmonic looks;

FIG. 14 is a diagram for explaining, in the harmonic processing circuit of the power amplifier circuit according to the third embodiment, how the circuit at a fundamental and an odd harmonic looks;

FIG. 15 is a diagram illustrating a power amplifier circuit according to a fourth embodiment;

FIG. 16 is a diagram illustrating an example of a harmonic processing circuit in FIG. 15;

FIG. 17 is a diagram illustrating another example of the harmonic processing circuit in FIG. 15; and

FIG. 18 is a diagram illustrating a power amplifier circuit according to a fifth embodiment.

### DETAILED DESCRIPTION OF THE DISCLOSURE

Embodiments of the present disclosure will be described in detail below with reference to the drawings. In a description of each of the following embodiments, components that are the same as or equivalent to those in other embodiments are denoted by the same reference signs, and a description thereof is simplified or omitted. The present disclosure is not to be limited by each embodiment. Furthermore, components in each embodiment include components that can be easily replaced by a person skilled in the art or substantially the same components. Note that configurations described below can be combined as appropriate. Furthermore, a configuration can be omitted, replaced, or changed without departing from the gist of the disclosure.

To facilitate understanding of embodiments, a comparative example will be described first below.

### Comparative Example

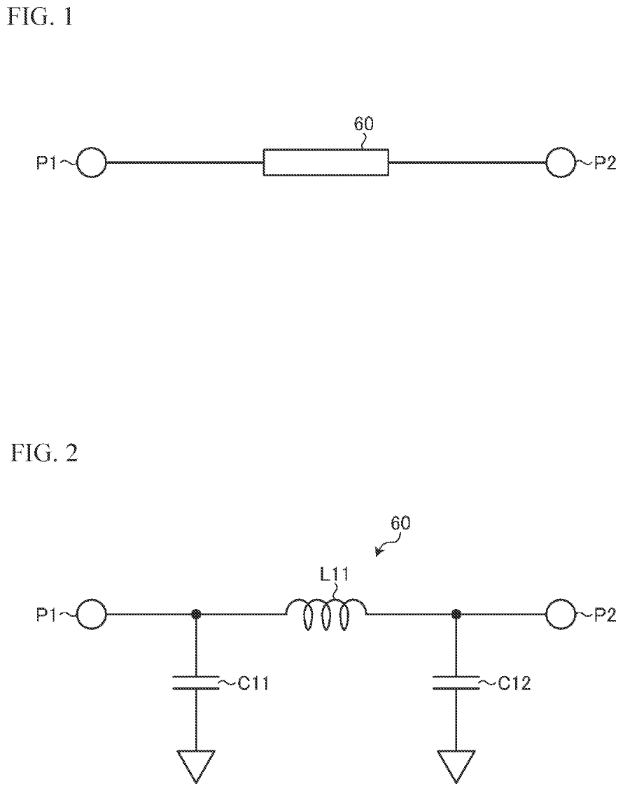

FIG. 1 is a diagram illustrating an example of a λ/4 transformer used in a Doherty amplifier circuit. A λ/4 transformer 60 illustrated in FIG. 1 includes, between a terminal P1 and a terminal P2, an element for delaying a phase by 90° (corresponding to a quarter of a wavelength).

FIG. 2 is a diagram illustrating an example of a more specific configuration of the λ/4 transformer. The λ/4 transformer 60 illustrated in FIG. 2 is a λ/4 transformer implemented by a lumped parameter circuit. The λ/4 transformer illustrated in FIG. 2 is a π-type transformer including an inductor L11, and capacitors C11 and C12. The inductor L11 is provided in series between the terminals P1 and P2.

One end of the capacitor C11 is connected between one end of the inductor L11 and the terminal P1. The other end of the capacitor C11 is connected to a reference potential. One end of the capacitor C12 is connected between the other end of the inductor L11 and the terminal P2. The other end of the capacitor C12 is connected to the reference potential. The reference potential is, for example, a ground potential. The same holds true for the following description.

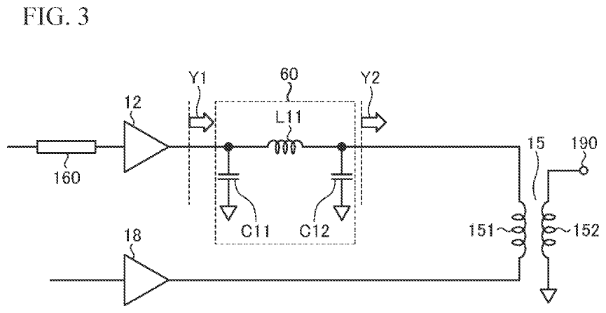

FIG. 3 is a diagram illustrating an example of a Doherty amplifier circuit using the λ/4 transformer 60 illustrated in FIG. 2. The Doherty amplifier circuit illustrated in FIG. 3 includes a phase shifter 160, amplifiers 12 and 18, the λ/4 transformer 60, a balun 15, and an output terminal 190. The amplifier 12 is a carrier amplifier of the Doherty amplifier circuit. The amplifier 18 is a peak amplifier of the Doherty amplifier circuit. The phase shifter 160 is provided on an input side of the amplifier 12. The phase shifter 160 delays a phase by 90°. The λ/4 transformer 60 is provided on an output side of the amplifier 12. The balun 15 includes an inductor 151 and an inductor 152.

In the Doherty amplifier circuit illustrated in FIG. 3, only the amplifier 12, which is a carrier amplifier, operates at a low output power level, and the amplifier 12, which is a carrier amplifier, and the amplifier 18, which is a peak amplifier, operate at a high output power level. In

FIG. 3, a characteristic impedance as seen from the position of an arrow Y1 looking toward an output side and a characteristic impedance as seen from the position of an arrow Y2 looking toward the output side will be described later.

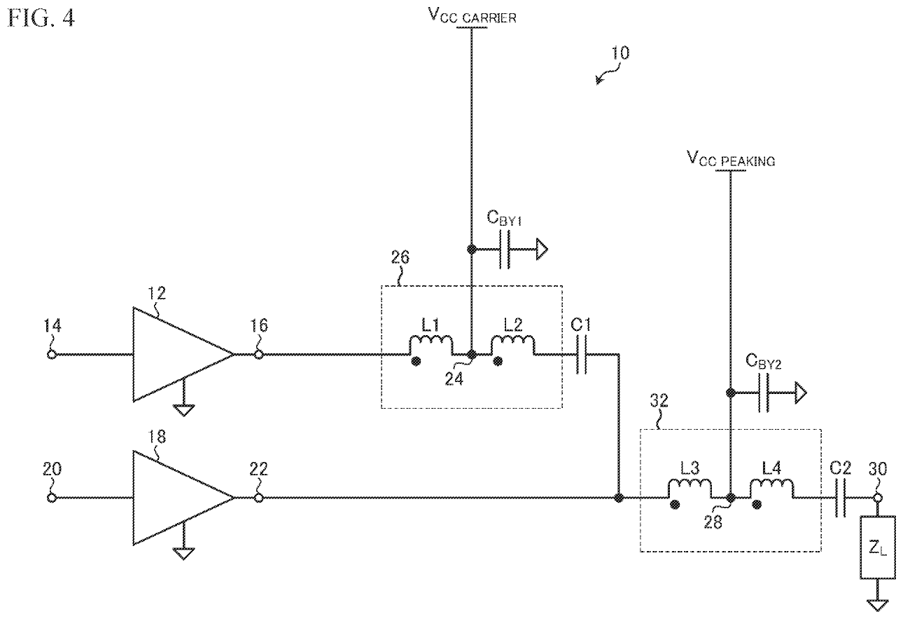

FIG. 4 is a diagram illustrating an example of a configuration of a Doherty amplifier circuit. A Doherty amplifier circuit 10 illustrated in FIG. 4 is disclosed in U.S. patent Application Publication No. 2021/0184633. In FIG. 4, the Doherty amplifier circuit 10 includes an amplifier 12, an amplifier 18, a first impedance inverter 26, a second impedance inverter 32, a capacitor C1, a capacitor C2, a capacitor C_{BY1}, and a capacitor C_{BY2}.

The amplifier 12 operates as a carrier amplifier. The amplifier 18 operates as a peak amplifier. The impedance inverters 26 and 32 are circuits that process a harmonic. An output terminal 16 of the amplifier 12 is connected to the impedance inverter 26. An output terminal 22 of the amplifier 18 is connected to the impedance inverter 32.

The impedance inverter 26 includes an inductor L1 and an inductor L2. Power of a power supply V_{CC CARRIER} for the amplifier 12 is supplied to a middle node 24, which is a connection point between the inductor L1 and the inductor L2. The inductor L2 of the impedance inverter 26 is connected to one end of the capacitor C1. The other end of the capacitor C1 is connected to the output terminal 22 of the amplifier 18.

The impedance inverter 32 includes an inductor L3 and an inductor L4. Power of a power supply V_{CC PEAKING} for the amplifier 18 is supplied to a middle node 28, which is a connection point between the inductor L3 and the inductor L4. The inductor L4 of the impedance inverter 32 is connected to one end of the capacitor C2. The other end of the capacitor C2 is connected to an output terminal 30 of the Doherty amplifier circuit 10. A load Z_{L} is connected to the output terminal 30.

The capacitor C_{BY1} is an RF grounding capacitor connected between the middle node 24 and the power supply V_{CC CARRIER} for the amplifier 12. The capacitor C_{BY2} is an RF grounding capacitor connected between the middle node 28 and the power supply V_{CC PEAKING} for the amplifier 18.

In a power amplifier circuit in a comparative example illustrated in FIG. 4, to cause the amplifiers 12 and 18 to operate with high efficiency, for example, a case is discussed in which class-F operation or inverse class-F operation is implemented. In this case, circuits that process a harmonic have to be further provided at output ends of the respective amplifiers 12 and 18 in addition to the impedance inverters 26 and 32. As for class-F operation, an L-C series resonant circuit that short-circuits a second harmonic impedance is added as a circuit that processes a harmonic, and this circuit has to be connected to a ground potential. Furthermore, as for inverse class-F operation, an L-C series resonant circuit that short-circuits a third harmonic impedance is added as a circuit that processes a harmonic, and this circuit has to be connected to the ground potential. Thus, in the power amplifier circuit in the comparative example, a circuit that processes a harmonic has to be provided for each of the peak amplifier and the carrier amplifier. This increases the number of circuit elements and interferes with a reduction in size of the power amplifier circuit.

### First Embodiment

Next, an embodiment will be described.

### Configuration

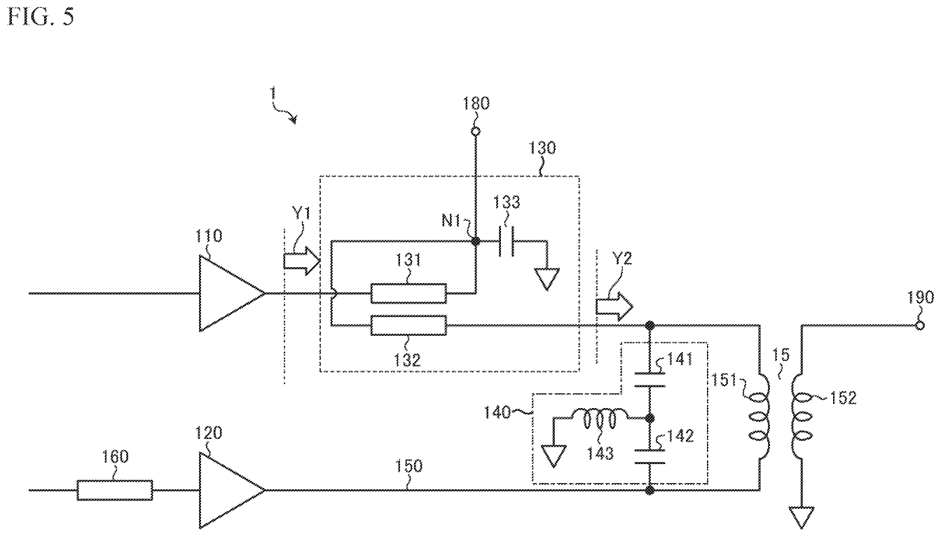

FIG. 5 is a diagram illustrating a power amplifier circuit 1 according to a first embodiment. In FIG. 5, the power amplifier circuit 1 according to the first embodiment includes an amplifier 110, an amplifier 120, an impedance conversion unit 130, a harmonic processing circuit 140, a phase shifter 160, a balun 15, and an output terminal 190.

The amplifier 110, which is a first amplifier, and the amplifier 120, which is a second amplifier, constitute a Doherty amplifier circuit. The amplifier 110 is, for example, a peak amplifier of the Doherty amplifier circuit. The amplifier 120 is, for example, a carrier amplifier of the Doherty amplifier circuit. Note that the amplifier 110 may be a carrier amplifier of the Doherty amplifier circuit and the amplifier 120 may be a peak amplifier of the Doherty amplifier circuit.

The impedance conversion unit 130 is connected to an output end of one amplifier, which is either the amplifier 110 or the amplifier 120. In this example, the impedance conversion unit 130 is connected to an output end of the amplifier 110. A line 150 at an output end of the other amplifier of the amplifier 110 and the amplifier 120 and a line 132 of the impedance conversion unit 130 are connected via the balun 15. That is, a signal based on a connection point between the line 150 at an output end of the amplifier 120 and the line 132 is outputted from the output terminal 190.

The balun 15 includes an inductor 151 and an inductor 152. One end of the inductor 151 is connected to the output end of the amplifier 110 via the impedance conversion unit 130. The other end of the inductor 151 is connected to the output end of the amplifier 120. The inductor 152 is coupled to the inductor 151 via a magnetic field. One end of the inductor 152 is connected to the output terminal 190 of the power amplifier circuit 1. The other end of the inductor 152 is connected to a reference potential.

The phase shifter 160 shifts a phase of an input signal by 90 degrees and outputs the signal. An output signal of the phase shifter 160 is inputted to the amplifier 120.

### Impedance Conversion Unit

The impedance conversion unit 130 includes a line 131, which is a first line, the line 132, which is a second line, and a capacitor 133, which is a first capacitor. One end of the line 131 is connected to the output end of the amplifier 110. The other end of the line 131 is connected to one end of the line 132. One end of the capacitor 133 is connected to a connection point N1 between the line 131 and the line 132. The other end of the capacitor 133 is connected to the reference potential. The connection point N1 is connected to a power supply 180.

The impedance conversion unit 130 uses not an inductor but the lines 131 and 132 that appear to be transmission lines. The line 131 and the line 132 are parallel plates. Specifically, the line 131 and the line 132 are disposed in parallel with each other, and each line is a plate-like conductor with a main surface facing the other line and being larger in area than a side surface not facing the other line. Patterns implementing the lines 131 and 132 are typically of linear shape. On the other hand, an inductor typically has a ring-shaped structure pattern. In this respect, the lines 131 and 132 differ from the inductor. The shapes of the line 131 and the line 132 are ideally a linear shape pattern. Note that, as described later, the lines 131 and 132 may have a folded-back structure.

The line 131 and the line 132 are coupled to each other. The distance between the line 131 and the line 132 is sufficiently short, and thus a coupling impedance between the lines is sufficiently low. However, both the lines 131 and 132 are able to be at a sufficient distance from the reference potential, and their structures provide isolation. A high impedance is presented at an in-phase frequency. A very low impedance is presented at a differential frequency. The impedance conversion unit 130 operates as a λ/4 transformer.

When the impedance conversion unit 130 is used, the circuits provided on the output sides of the respective amplifiers in the comparative example are unnecessary, and one impedance conversion unit 130 can implement desired operation.

### Harmonic Processing Circuit

The harmonic processing circuit 140 is a common circuit provided for the amplifier 110 and the amplifier 120. The harmonic processing circuit 140 is provided as a common circuit for the amplifier 110 and the amplifier 120, and thus the harmonic processing circuit 140 may not be provided for each of the amplifier 110 and the amplifier 120. This enables a reduction in size of the power amplifier circuit. Incidentally, the harmonic processing circuit 140 is connected in parallel with the inductor 151.

The harmonic processing circuit 140 includes a third capacitor 141, a fourth capacitor 142, and a second inductor 143. One end of the third capacitor 141 is connected to an output end of the impedance conversion unit 130. One end of the fourth capacitor 142 is connected to the line 150, that is, to the output end of the amplifier 120. The other end of the third capacitor 141 and the other end of the fourth capacitor 142 are connected to each other. One end of the second inductor 143 is connected to a connection point between the third capacitor 141 and the fourth capacitor 142. The other end of the second inductor 143 is connected to the reference potential.

### Passage Loss

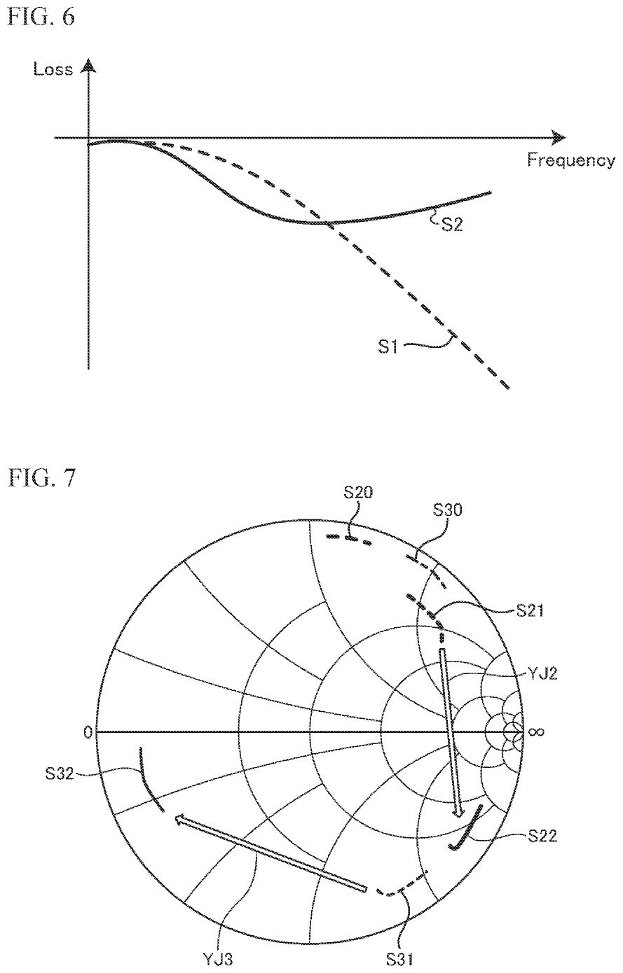

FIG. 6 is a graph illustrating an example of passage loss for frequency. In FIG. 6, the horizontal axis represents frequency (Frequency), and the vertical axis represents passage loss (Loss). In a vertical axis direction in FIG. 6, a larger passage loss is represented on the lower side in FIG. 6, and a smaller passage loss is represented on the upper side.

In a horizontal axis direction in FIG. 6, a frequency near an intersection with the vertical axis in FIG. 6 is a fundamental frequency, which is a frequency of a fundamental. In FIG. 6, frequencies on the right side with respect to the vertical axis are frequencies, such as frequencies of a second harmonic and a third harmonic, higher than the fundamental.

A characteristic S1 in FIG. 6 represents an example of passage loss exhibited when the λ/4 transformer illustrated in FIG. 2 or the impedance inverter 26 illustrated in FIG. 4 is employed. A characteristic S2 in FIG. 6 represents an example of passage loss exhibited when the impedance conversion unit 130 in FIG. 5 is used.

The λ/4 transformer illustrated in FIG. 2 and the impedance inverter 26 illustrated in FIG. 4 include an inductor. For this reason, for the characteristic S1, the passage loss increases as the frequency increases. On the other hand, the impedance conversion unit 130 illustrated in FIG. 5 uses not an inductor but the lines 131 and 132, which are transmission lines. Hence, referring to FIG. 6, for both the characteristic S1 and the characteristic S2, there is little passage loss at the fundamental frequency near the vertical axis. However, focusing on the characteristic S1, the passage loss increases at frequencies higher than the fundamental frequency. On the other hand, focusing on the characteristic S2 in which the impedance conversion unit 130 is used, it can be seen that the characteristic S2 is smaller in passage loss than the characteristic S1 not only at the fundamental frequency but also at frequencies higher than the fundamental frequency. Unlike an inductor, a small passage loss is exhibited at high frequencies, and thus it can be seen that characteristics close to transmission line characteristics can be obtained by using the impedance conversion unit 130.

As for the comparative example described with reference to FIG. 4, if a harmonic is desired to be processed, harmonic processing circuits are provided at the output ends of the respective amplifiers 12 and 18. On the other hand, in the power amplifier circuit according to the present disclosure, desired operation can be implemented only by connecting the harmonic processing circuit 140 to a stage subsequent to the impedance conversion unit 130.

### Characteristic Impedance

FIG. 7 is a Smith chart for explaining a characteristic impedance of the power amplifier circuit according to the present disclosure by comparison with that in the comparative example.

A characteristic S20 represents, for a second harmonic, an example of characteristic impedance exhibited when the configuration in FIG. 2 or the impedance inverter 26 in FIG. 4 is used. In the case in FIG. 3, the characteristic S20 represents a characteristic impedance as seen from the output end of the amplifier 12 looking toward an output terminal 190 side as in the arrow Y1.

A characteristic S30 represents, for a third harmonic, an example of characteristic impedance exhibited when the configuration in FIG. 2 or the impedance inverter 26 in FIG. 4 is used. In the case in FIG. 3, the characteristic S30 represents a characteristic impedance as seen from the λ/4 transformer 60 looking toward the output terminal 190 side as in the arrow Y2.

As for the comparative example (FIGS. 2 and 4), the passage loss increases at frequencies higher than the fundamental frequency (see FIG. 6). For this reason, isolation is provided in the impedance inverter 26, and, regardless of where the location of an original characteristic impedance is, a characteristic impedance remains stuck, for example, to the location of the characteristic S20 for the second harmonic or to the location of the characteristic S30 for the third harmonic.

In contrast to the above-described characteristics S20 and S30, when the impedance conversion unit 130 and the harmonic processing circuit 140 are used as illustrated in FIG. 5, the following characteristics S21, S22, S31, and S32 are exhibited.

The characteristic S21 represents, for the second harmonic, a characteristic impedance as seen from the output end of the impedance conversion unit 130 looking toward an output terminal 190 side as indicated by an arrow Y2 in FIG. 5. The characteristic S21 is a characteristic impedance that is unaffected by the impedance conversion unit 130.

The characteristic S22 represents, for the second harmonic, a characteristic impedance as seen from the output end of the amplifier 110 looking toward the output terminal 190 side including the impedance conversion unit 130 as indicated by an arrow Y1 in FIG. 5. When the impedance conversion unit 130 is provided, for the second harmonic, the location of the characteristic S21 can be moved to the location of the characteristic S22 close to an open circuit. Specifically, when the impedance conversion unit 130 according to the present disclosure is used, the passage loss decreases at frequencies higher than the fundamental frequency, and thus the characteristic impedance can be moved from the location of an original characteristic impedance to a location obtained by shifting a phase by a predetermined amount. That is, as indicated by an arrow YJ2 in FIG. 7, for the second harmonic, the characteristic impedance can be moved to the location close to the open circuit while the phase is rotated.

The characteristic S31 represents, for the third harmonic, a characteristic impedance as seen from the output end of the impedance conversion unit 130 looking toward the output terminal 190 side as indicated by the arrow Y2 in FIG. 5. The characteristic S31 is a characteristic impedance that is unaffected by the impedance conversion unit 130.

The characteristic S32 represents, for the third harmonic, a characteristic impedance as seen from the output end of the amplifier 110 looking toward the output terminal 190 side including the impedance conversion unit 130 as indicated by the arrow Y1 in FIG. 5. When the impedance conversion unit 130 is provided, for the third harmonic, the location of the characteristic S31 can be moved to the location of the characteristic S32 close to a short circuit. That is, as indicated by an arrow YJ3 in FIG. 7, for the third harmonic, the characteristic impedance can be moved to the location close to the short circuit while a phase is rotated.

As described above, the characteristic S22 represents the second harmonic, and the characteristic S32 represents the third harmonic. In FIG. 7, the characteristic S22 is located close to the open circuit, and the characteristic S32 is located close to the short circuit. Hence, characteristics for inverse class-F operation can be obtained in which the open circuit is provided for the second harmonic, which is an even harmonic, and in which the short circuit is provided for the third harmonic, which is an odd harmonic. Incidentally, assuming that a reference impedance Zref is 10 Ω and the fundamental frequency is 3.7 GHz, capacitance values of the third capacitor 141 and the fourth capacitor 142 in the harmonic processing circuit 140 in FIG. 5 are, for example, 4.2 pF, and an inductance value of the second inductor 143 is, for example, 0.42 nH.

Although FIG. 7 illustrates characteristics impedance in a case where inverse class-F operation is implemented, characteristics for class-F operation can be obtained by adjusting values of elements in the harmonic processing circuit 140. That is, when a value of each element in the harmonic processing circuit 140 is adjusted, characteristics for class-F operation can be obtained in which the short circuit is provided for the second harmonic, which is an even harmonic, and in which the open circuit is provided for the third harmonic, which is an odd harmonic.

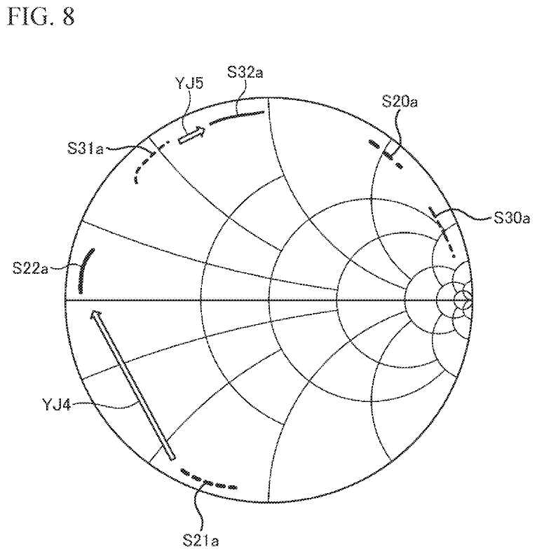

FIG. 8 is a Smith chart for explaining a characteristic impedance of the power amplifier circuit according to the present disclosure by comparison with that in the comparative example. FIG. 8 illustrates an example of a case where class-F operation is implemented. A characteristic S20a represents, for the second harmonic, an example of characteristic impedance exhibited when the configuration in FIG. 2 or the impedance inverter 26 in FIG. 4 is used. A characteristic S30a represents, for the third harmonic, an example of characteristic impedance exhibited when the configuration in FIG. 2 or the impedance inverter 26 in FIG. 4 is used. As for the comparative example (FIGS. 2 and 4), regardless of where the location of an original characteristic impedance is, a characteristic impedance remains stuck, for example, to the location of the characteristic S20a for the second harmonic or to the location of the characteristic S30a for the third harmonic. In contrast to the above-described characteristics S20a and S30a, when an impedance conversion unit and a harmonic processing circuit that implement class-F operation are used, the following characteristics S21a, S22a, S31a, and S32a are exhibited.

The characteristic S21a represents, for the second harmonic, a characteristic impedance as seen from an output end of the impedance conversion unit looking toward the output terminal side. The characteristic S21a is a characteristic impedance that is unaffected by the impedance conversion unit. The characteristic S22a represents, for the second harmonic, a characteristic impedance as seen from the output end of the amplifier 110 looking toward the output terminal side including the impedance conversion unit. When the impedance conversion unit is provided, for the second harmonic, the location of the characteristic S21aa can be moved to the location of the characteristic S22a close to a short circuit as indicated by an arrow YJ4 in FIG. 8.

The characteristic S31a represents, for the third harmonic, a characteristic impedance as seen from the output end of the impedance conversion unit looking toward the output terminal side. As indicated by an arrow YJ5 in FIG. 8, the characteristic impedance can be moved to the location of the characteristic S32a shifted closer to an open circuit.

### Operation

In FIG. 5, the power amplifier circuit 1 according to the first embodiment operates as a Doherty amplifier circuit in which the amplifier 110 is a peak amplifier and the amplifier 120 is a carrier amplifier. Only the amplifier 120, which is a carrier amplifier, operates at a low output power level. Both the amplifier 110 and the amplifier 120 operate at a high output power level.

A signal based on a connection point between the line 150 at the output end of the amplifier 120 and the line 132 is outputted from the output terminal 190 via the balun 15. Since the inductor 151, which is a primary winding of the balun 15, and the inductor 152, which is a secondary winding, are magnetically coupled to each other, a voltage at a primary side of the balun 15 is transmitted to a secondary side. That is, the power amplifier circuit 1 according to this embodiment operates as a voltage combining-type Doherty amplifier circuit.

In a case where inverse class-F operation is implemented, the power amplifier circuit 1 converts a characteristic impedance looking toward the output terminal side by using the impedance conversion unit 130 and the harmonic processing circuit 140. In the case where inverse class-F operation is implemented, the characteristic impedance is moved to a location corresponding to an open circuit for the second harmonic, which is an even harmonic, and the characteristic impedance is moved to a location corresponding to a short circuit for the third harmonic, which is an odd harmonic. Hence, highly efficient operation can be implemented.

Furthermore, in a case where class-F operation is implemented, the power amplifier circuit 1 converts a characteristic impedance looking toward the output terminal side by using the impedance conversion unit 130 and the harmonic processing circuit 140. In the case where class-F operation is implemented, the characteristic impedance is moved to a location corresponding to a short circuit for the second harmonic, which is an even harmonic, and the characteristic impedance is moved to a location corresponding to an open circuit for the third harmonic, which is an odd harmonic. Hence, highly efficient operation can be implemented.

Furthermore, when one harmonic processing circuit 140 provided as a common circuit for two amplifiers 110 and 120 is used, the location of a characteristic impedance can be adjusted to any location. The one harmonic processing circuit 140 can adjust a characteristic impedance for the second harmonic and a characteristic impedance for the third harmonic, and thus, when the power amplifier circuit 1 is caused to implement class-F operation or inverse class-F operation, the number of harmonic processing circuits can be reduced in comparison with that in the comparative example (see FIG. 4). This enables a reduction in size of the power amplifier circuit.

### Second Embodiment

### Configuration

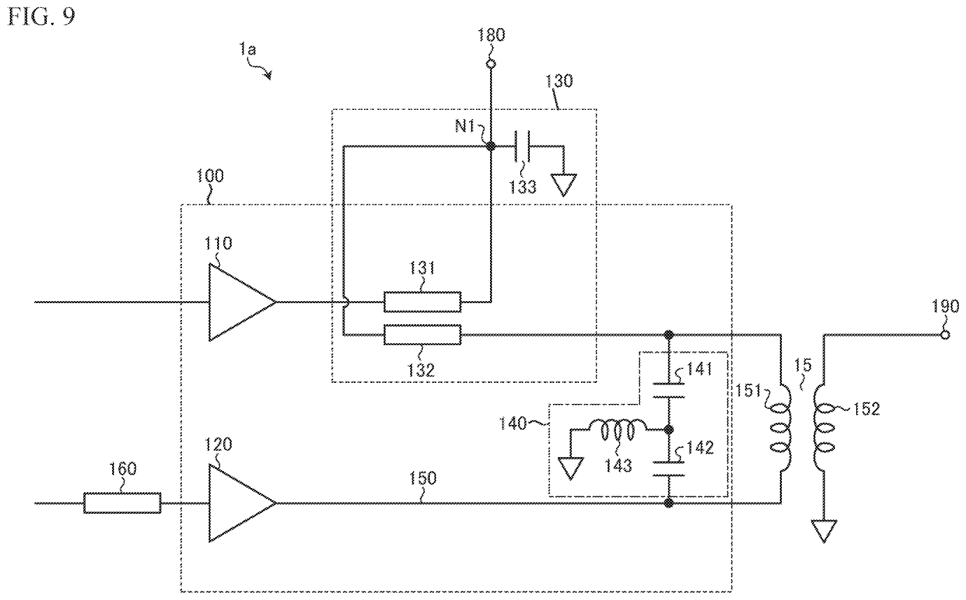

FIG. 9 is a diagram illustrating a power amplifier circuit 1a according to a second embodiment. In FIG. 9, the power amplifier circuit 1a according to the second embodiment is a circuit obtained by constructing the power amplifier circuit 1 according to the first embodiment with a semiconductor substrate 100. On or above the semiconductor substrate 100, the amplifiers 110 and 120, the lines 131 and 132 of the impedance conversion unit 130, and the harmonic processing circuit 140 are formed. In this example, the capacitor 133 of the impedance conversion unit 130 is formed outside the semiconductor substrate 100.

FIG. 10 is a plan view illustrating a pattern example in a case where the power amplifier circuit 1a according to the second embodiment is formed on the semiconductor substrate 100. FIG. 10 schematically illustrates a layout of the semiconductor substrate 100.

As illustrated in FIG. 10, on or above the semiconductor substrate 100, the amplifiers 110 and 120, the impedance conversion unit 130, and the harmonic processing circuit 140 are formed. Furthermore, on or above the semiconductor substrate 100, the amplifier 110 and the amplifier 120 are arranged in an X-axis direction. Additionally, on or above the semiconductor substrate 100, the impedance conversion unit 130 and the line 150, and the amplifiers 110 and 120 are arranged opposite to the harmonic processing circuit 140 in a Y-axis direction.

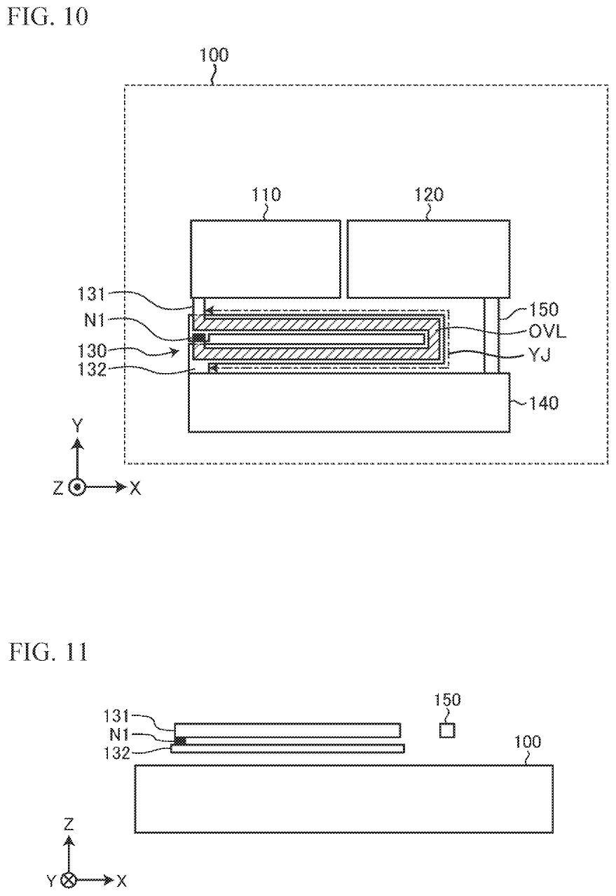

FIG. 11 is a perspective view of an impedance conversion unit 130 side as viewed from a harmonic processing circuit 140 side in FIG. 10. As illustrated in FIGS. 10 and 11, above the semiconductor substrate 100, the line 132 is formed, and the line 131 is further formed above the line 132. Note that FIG. 11 does not illustrate, for example, insulating layers provided among the semiconductor substrate 100, the line 131, the line 132, and the line 150.

The line 132 extends as indicated by an arrow YJ of a dashed-dotted line in FIG. 10. That is, the line 132 extends from a connection portion between the line 132 and the harmonic processing circuit 140 in the Y-axis direction and then extends in the X-axis direction. The line 132 further extends in the Y-axis direction and then extends in a direction opposite to the X-axis direction. Then, the line 132 extends slightly in a direction opposite to the Y-axis direction, and a slightly extended portion is a termination portion of the line 132. That is, the slightly extended portion is a termination portion that is opposite to the connection portion between the line 132 and the harmonic processing circuit 140. This termination portion is electrically connected to the line 131 by the connection point N1. The connection point N1 is, for example, a via hole connecting the line 131 and the line 132. Thus, the line 132 has a folded-back structure in which the line 132 extends in the X-axis direction and then extends in the direction opposite to the X-axis direction.

The line 131 extends from a connection portion between the line 131 and the amplifier 110 in the direction opposite to the Y-axis direction and then extends in the X-axis direction. The line 131 further extends in the direction opposite to the Y-axis direction and then extends in the direction opposite to the X-axis direction. Then, the line 131 extends slightly in the Y-axis direction, and a slightly extended portion is a termination portion of the line 131. That is, the slightly extended portion is a termination portion that is opposite to the connection portion between the line 131 and the amplifier 110. This termination portion is electrically connected to the line 132 by the connection point N1. Thus, the line 131 has a folded-back structure in which the line 131 extends in the X-axis direction and then extends in the direction opposite to the X-axis direction. Incidentally, the capacitor 133 (see FIG. 9), which is not illustrated, is connected to the connection point N1. Furthermore, the power supply 180 (see FIG. 9) is connected to the connection point N1.

As illustrated in FIGS. 10 and 11, the line 131, which is a first pattern, and the line 132, which is a second pattern, have an overlap portion OVL (hatched portion in FIG. 10) when the semiconductor substrate 100 is viewed in plan. It is desirable that the length of the overlap portion OVL (length along a path along which each line extends) be not greater than a quarter of the wavelength of the fundamental.

As illustrated in FIG. 10, in this example, the width of the line 131 differs from the width of the line 132, but these widths may be the same. A width herein refers to a length along a direction perpendicular to a direction in which the line 131 or 132 extends.

Furthermore, as illustrated in FIG. 11, in this example, the thickness of the line 131 differs from the thickness of the line 132, but these thicknesses may be the same. A thickness herein refers to the length of the line 131 or 132 in a Z-axis direction.

### Operation

Operation of the power amplifier circuit 1a according to this embodiment is similar to the operation of the power amplifier circuit 1 according to the first embodiment.

### Third Embodiment

### Configuration

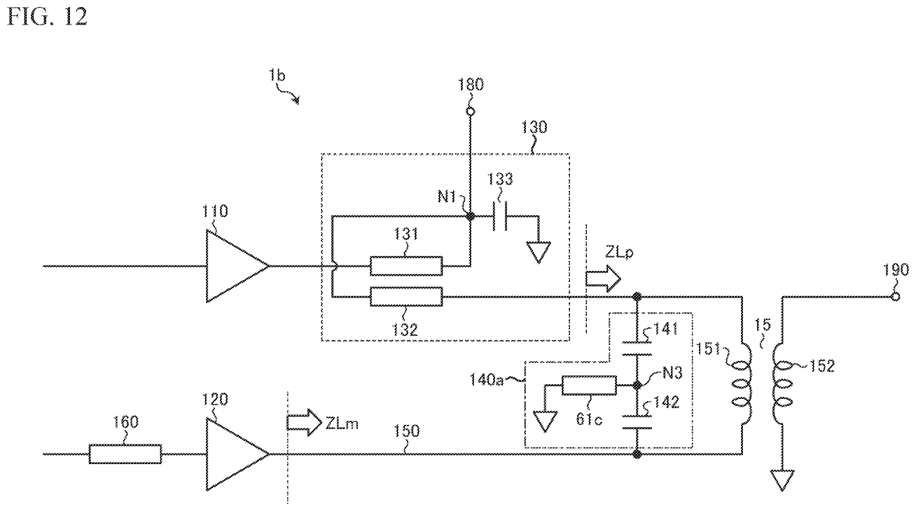

FIG. 12 is a diagram illustrating a power amplifier circuit 1b according to a third embodiment. The power amplifier circuit 1b according to the third embodiment employs, in place of the harmonic processing circuit 140 in the power amplifier circuit 1 according to the first embodiment, a harmonic processing circuit 140a using a microstrip line.

In FIG. 12, the harmonic processing circuit 140a includes the third capacitor 141, the fourth capacitor 142, and a microstrip line 61_{c}. The one end of the third capacitor 141 is connected to the output end of the impedance conversion unit 130. The one end of the fourth capacitor 142 is connected to the line 150, that is, to the output end of the amplifier 120. The other end of the third capacitor 141 and the other end of the fourth capacitor 142 are connected at a connection point N3. One end of the microstrip line 61c is connected to the connection point N3. The other end of the microstrip line 61c is connected to the reference potential. The microstrip line 61c is formed, for example, in a linear shape.

### Operation

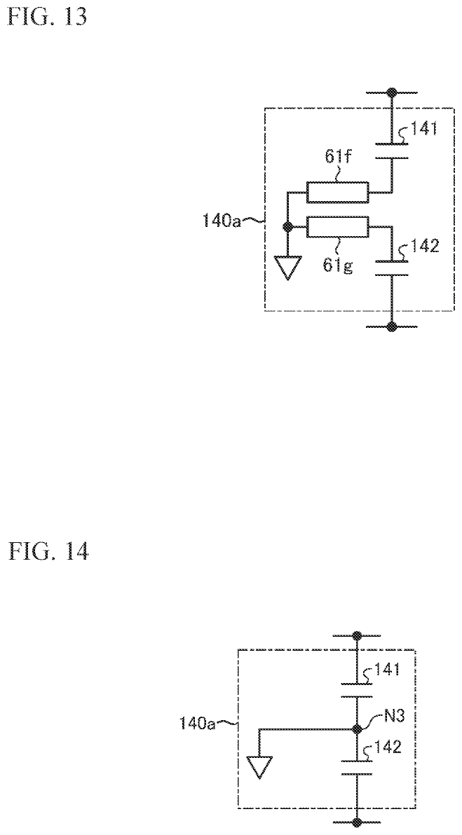

FIG. 13 is a diagram for explaining, in the harmonic processing circuit 140a of the power amplifier circuit 1b according to the third embodiment, how the circuit at an even harmonic looks. At an even harmonic, a phase of a signal outputted from the impedance conversion unit 130 is substantially the same as a phase of a signal outputted from the output end of the amplifier 120, and thus a potential at the output end of the impedance conversion unit 130 and a potential at the output end of the amplifier 120 are substantially the same. For this reason, no current flows from the output end of the impedance conversion unit 130 to the line 150 at the output end of the amplifier 120 through the third capacitor 141 and the fourth capacitor 142. Hence, from the output end of the impedance conversion unit 130, the output end of the impedance conversion unit 130 does not appear to be connected to the line 150 at the output end of the amplifier 120 through the third capacitor 141 and the fourth capacitor 142.

On the other hand, the potential at the output end of the impedance conversion unit 130 differs from the reference potential, and thus a current flows from the output end of the impedance conversion unit 130 toward the reference potential through the third capacitor 141 and the microstrip line 61_{c}. Hence, from the output end of the impedance conversion unit 130, the output end of the impedance conversion unit 130 appears to be connected to the reference potential through the third capacitor 141 and the microstrip line 61c.

For an even harmonic, an impedance ZLp as seen from the output end of the impedance conversion unit 130 looking toward the harmonic processing circuit 140a can be adjusted by the capacitance of the third capacitor 141 and the inductance of a microstrip line 61_{f}. Similarly, for an even harmonic, an impedance ZLm as seen from the output end of the amplifier 120 looking toward the harmonic processing circuit 140a can also be adjusted by the capacitance of the fourth capacitor 142 and the inductance of a microstrip line 61g.

FIG. 14 is a diagram for explaining, in the harmonic processing circuit 140a of the power amplifier circuit 1b according to the third embodiment, how the circuit at the fundamental and an odd harmonic looks. As illustrated in FIG. 14, at the fundamental and an odd harmonic, a phase of a signal outputted from the impedance conversion unit 130 differs from a phase of a signal outputted from the output end of the amplifier 120 by substantially 180 degrees, and thus the connection point N3 is virtually short-circuited. Hence, from the output end of the impedance conversion unit 130, the output end of the impedance conversion unit 130 appears to be connected to the reference potential through the third capacitor 141. Similarly, from the output end of the amplifier 120, the output end of the amplifier 120 appears to be connected to the reference potential through the fourth capacitor 142.

For the fundamental and an odd harmonic, the impedance ZLp as seen from the output end of the impedance conversion unit 130 looking toward the harmonic processing circuit 140a can be adjusted by the capacitance of the third capacitor 141. Similarly, for the fundamental and an odd harmonic, the impedance ZLm as seen from the output end of the amplifier 120 looking toward the harmonic processing circuit 140a can also be adjusted by the capacitance of the fourth capacitor 142.

### Fourth Embodiment

### Configuration

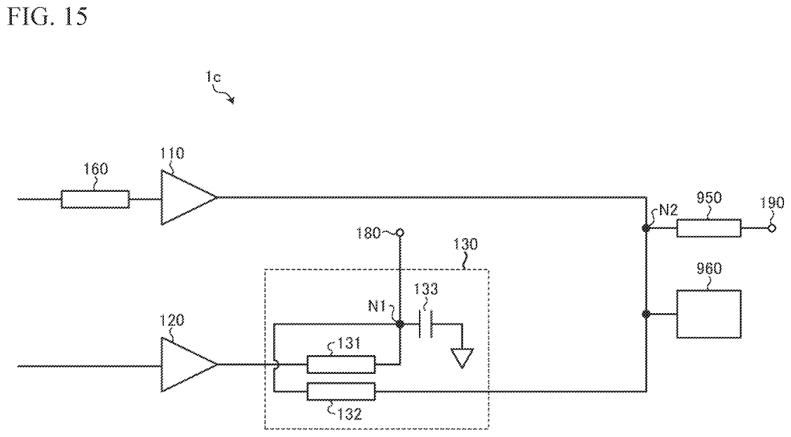

FIG. 15 is a diagram illustrating a power amplifier circuit 1c according to a fourth embodiment. The power amplifier circuits 1 to 1b according to the first embodiment to the third embodiment are a voltage combining-type Doherty amplifier circuit. On the other hand, the power amplifier circuit 1c according to the fourth embodiment is a current combining-type Doherty amplifier circuit.

In FIG. 15, in the power amplifier circuit 1c according to the fourth embodiment, the phase shifter 160 is provided on an input side of the amplifier 110, which is a peak amplifier. Furthermore, the impedance conversion unit 130 is provided on an output side of the amplifier 120, which is a carrier amplifier. The output end of the amplifier 110 and the output end of the amplifier 120 are connected via the impedance conversion unit 130. Between a connection point N2 at which these output ends are connected to each other and the output terminal 190, a matching network 950 is provided. Furthermore, a harmonic processing circuit 960 is connected to the connection point N2. In the power amplifier circuit 1c according to the fourth embodiment, the harmonic processing circuit 960 is used in place of the harmonic processing circuit 140 used in the power amplifier circuit 1 (see FIG. 5) and the power amplifier circuit 1a (see FIG. 9).

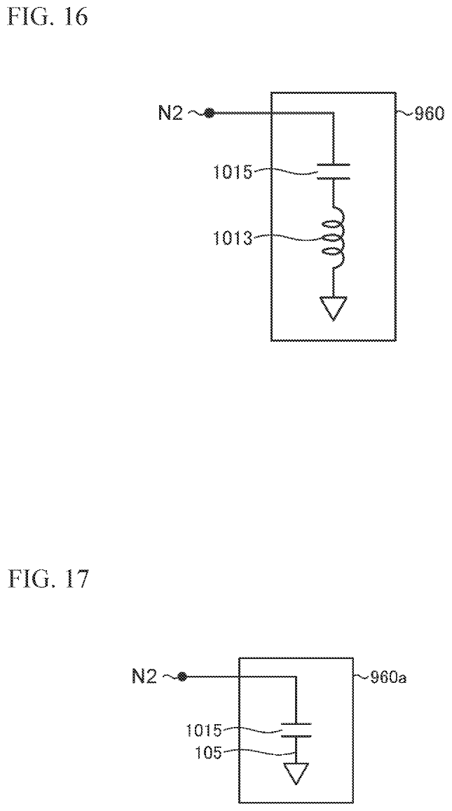

FIG. 16 is a diagram illustrating an example of the harmonic processing circuit 960 in FIG. 15. In FIG. 16, the harmonic processing circuit 960 includes an inductor 1013 and a capacitor 1015. One end of the inductor 1013 is connected to the reference potential. One end of the capacitor 1015 is connected to the connection point N2. The other end of the inductor 1013 and the other end of the capacitor 1015 are connected to each other. The inductor 1013 and the capacitor 1015 that are connected in series operate as a series resonant circuit. That is, the harmonic processing circuit 960 is a series resonant circuit including the inductor 1013, which is a first inductor, and the capacitor 1015, which is a second capacitor, that are connected in series and having, of a series connection, one end connected to the reference potential.

FIG. 17 is a diagram illustrating another example of the harmonic processing circuit 960 in FIG. 15. In FIG. 17, a harmonic processing circuit 960a includes the capacitor 1015. One end of the capacitor 1015 is connected to the connection point N2. The other end of the capacitor 1015 is connected to the reference potential via a line 105. The harmonic processing circuit 960a has a configuration in which an inductance component of the line 105 and a capacitance component of the capacitor 1015 are connected in series and operates as a series resonant circuit.

### Operation

Referring back to FIG. 15, in the power amplifier circuit 1c according to this embodiment, an output current of the amplifier 120, which is a carrier amplifier, reaches the connection point N2 via the impedance conversion unit 130. Furthermore, an output current of the amplifier 110, which is a peak amplifier, reaches the connection point N2.

The output currents are combined together at the connection point N2. A current obtained by combining the currents together at the connection point N2, that is, an amplified signal subjected to combination of currents is outputted from the output terminal 190 via the matching network 950. Thus, the power amplifier circuit 1c according to the fourth embodiment operates as a current combining-type Doherty amplifier circuit.

### Fifth Embodiment

### Configuration

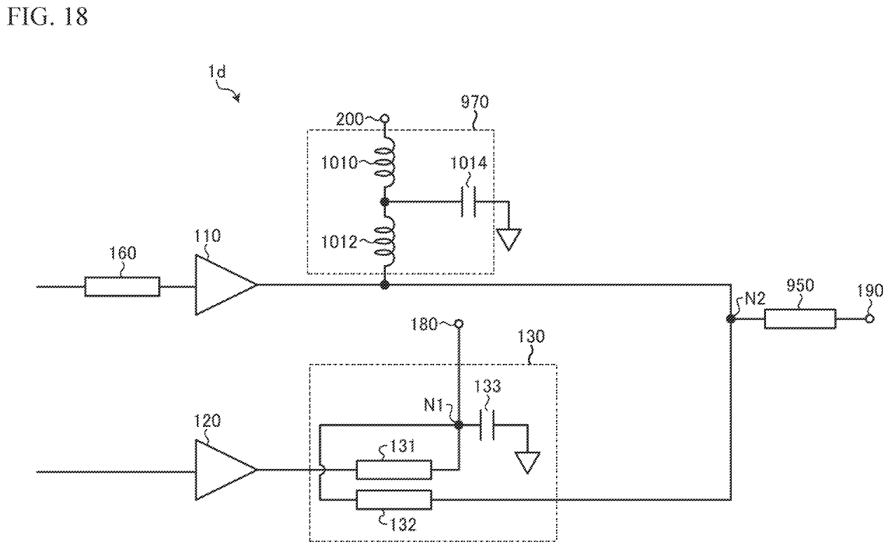

FIG. 18 is a diagram illustrating a power amplifier circuit 1d according to a fifth embodiment. In FIG. 18, the power amplifier circuit 1d according to the fifth embodiment uses a harmonic processing circuit 970 in place of the harmonic processing circuit 960 in FIG. 15. The harmonic processing circuit 970 includes an inductor 1010, an inductor 1012, and a capacitor 1014.

One end of the inductor 1010 is connected to a power supply 200. One end of the inductor 1012 is connected to the output end of the amplifier 110. The other end of the inductor 1010 and the other end of the inductor 1012 are connected to each other. One end of the capacitor 1014 is connected to a connection point between the inductor 1010 and the inductor 1012. The other end of the capacitor 1014 is connected to the reference potential. The harmonic processing circuit 970 short-circuits an impedance at a second harmonic frequency or third harmonic frequency by using resonance between the inductor 1012 and the capacitor 1014. The harmonic processing circuit 970 is a common circuit provided for the amplifier 110 and the amplifier 120. The harmonic processing circuit 970 is provided as a common circuit for the amplifier 110 and the amplifier 120, and thus the harmonic processing circuit 970 may not be provided for each of the amplifier 110 and the amplifier 120. This enables a reduction in size of the power amplifier circuit.

### Operation

In the power amplifier circuit 1d according to this embodiment, an output current of the amplifier 120, which is a carrier amplifier, reaches the connection point N2 via the impedance conversion unit 130. Furthermore, an output current of the amplifier 110, which is a peak amplifier, reaches the connection point N2. The output currents are combined together at the connection point N2. A current obtained by combining the currents together at the connection point N2, that is, an amplified signal subjected to combination of currents is outputted from the output terminal 190 via the matching network 950. Thus, the power amplifier circuit 1d according to the fifth embodiment operates as a current combining-type Doherty amplifier circuit.

### Modification

Although the above describes the case where the amplifier 110 and the amplifier 120 operate as a Doherty amplifier circuit, the present disclosure can be applied not only to a Doherty amplifier circuit, but also to a power amplifier circuit including a plurality of amplifiers. For example, the present disclosure can be applied to a case where the amplifier 110 and the amplifier 120 operate as a balanced amplifier circuit.

What is claimed is:

1. A power amplifier circuit comprising:
a first amplifier;
a second amplifier;
an output terminal; and
an impedance conversion circuit connected to an output end of one of the first amplifier or the second amplifier,
wherein the impedance conversion circuit comprises:
a first line with a first end connected to the output end,
a second line with a first end connected to a second end of the first line, and
a first capacitor with a first end connected to a node between the first line and the second line, and with a second end connected to a reference potential,
wherein the first line and the second line are coupled to each other, and
wherein a signal is output from the output terminal, the signal being based on a node between an output end of another of the first amplifier and the second amplifier that is not connected to the impedance conversion circuit and a second end of the second line.

2. The power amplifier circuit according to claim 1,
wherein the first amplifier and the second amplifier constitute a Doherty amplifier circuit,
wherein one of the first amplifier or the second amplifier is a peak amplifier of the Doherty amplifier circuit, and
wherein another of the first amplifier and the second amplifier is a carrier amplifier of the Doherty amplifier circuit.

3. The power amplifier circuit according to claim 2, further comprising:
a harmonic processing circuit between the impedance conversion circuit and the output terminal.

4. The power amplifier circuit according to claim 3, wherein the harmonic processing circuit is a common circuit to the first amplifier and the second amplifier.

5. The power amplifier circuit according to claim 3, wherein the harmonic processing circuit is a series resonant circuit comprising a first inductor and a second capacitor that are connected in series, and having one end connected to the reference potential.

6. The power amplifier circuit according to claim 3, wherein the harmonic processing circuit comprises a second capacitor with a first end connected to the reference potential.

7. The power amplifier circuit according to claim 3, further comprising:
a balun between the harmonic processing circuit and the output terminal,
wherein the harmonic processing circuit comprises:
a third capacitor with a first end connected to an output end of the impedance conversion circuit,
a fourth capacitor with a first end connected to an output end of the carrier amplifier, and
a second inductor,
wherein a second end of the third capacitor and a second end of the fourth capacitor are connected to each other,
wherein a first end of the second inductor is connected to a node between the second end of the third capacitor and the second end of the fourth capacitor,
wherein a second end of the second inductor is connected to the reference potential, and
wherein an amplified signal subjected to a combination of voltages is output from the output terminal via the balun.

8. The power amplifier circuit according to claim 3, further comprising:
a balun between the harmonic processing circuit and the output terminal,
wherein the harmonic processing circuit comprises:
a third inductor with a first end connected to an output end of the carrier amplifier, and
a fourth inductor with a first end connected to a second end of the third inductor, and a fourth capacitor with a first end connected to a node between the third inductor and the fourth inductor,
wherein a second end of the fourth inductor is connected to a power supply potential,
wherein a second end of the fourth capacitor is connected to the reference potential, and
wherein an amplified signal subjected to a combination of voltages is output from the output terminal via the balun.

9. The power amplifier circuit according to claim 2,
wherein an output end of the peak amplifier and an output end of the carrier amplifier are connected via the impedance conversion circuit,
wherein the power amplifier circuit further comprises a matching network between a node between the output end of the peak amplifier and the output end of the carrier amplifier, and the output terminal, and
wherein an amplified signal subjected to a combination of currents is output from the output terminal via the matching network.

10. The power amplifier circuit according to claim 3,
wherein an output end of the peak amplifier and an output end of the carrier amplifier are connected via the impedance conversion circuit,
wherein the power amplifier circuit further comprises a matching network between a node between the output end of the peak amplifier and the output end of the carrier amplifier, and the output terminal, and
wherein an amplified signal subjected to a combination of currents is output from the output terminal via the matching network.

11. The power amplifier circuit according to claim 1,
wherein the first line has a first pattern on a semiconductor substrate,
wherein the second line has a second pattern on the semiconductor substrate,
wherein the first pattern and the second pattern overlap when the semiconductor substrate is viewed in a plan view, and
wherein a length of a portion of the first and second patterns that overlap is not greater than a quarter of a wavelength of a fundamental frequency.
